(19) United States
(12) Patent Application Publication
(10) Pub. No.: US 2026/0262480 A1
(43) Pub. Date: Sep. 3, 2026

(54) SAMPLE SURFACE INSPECTION APPARATUS

(71) Applicant: Hitachi High-Tech Corporation, Tokyo (JP)

(72) Inventors: Katsuhiko KIMURA, Tokyo (JP); Yoshihiro SATOU, Tokyo (JP); Masaya YAMAMOTO, Tokyo (JP); Ayumi TOMIYAMA, Tokyo (JP)

(73) Assignee: Hitachi High-Tech Corporation, Tokyo (JP)

(21) Appl. No.: 18/995,620

(22) PCT Filed: Aug. 10, 2022
(86) PCT No.: PCT/JP2022/030610

§ 371 Date: Jan. 16, 2025

(51) Int. Cl. H10P 72/76; G01N 21/88

(52) U.S. Cl. CPC H10P 72/7624; G01N 21/88

(57) ABSTRACT

A sample surface inspection device comprises: a sample holding member; a spindle motor that rotates the sample holding member; a turntable fixed to the spindle motor; and a focus drive mechanism that displaces the sample holding member. The focus drive mechanism comprises: several support members of which one end is fixed to the sample holding member and the other end is fixed to the turntable, the support members support the sample holding member to be displaceable in the focus direction that is the height direction with respect to the turntable; a yoke; a magnet that is fixed to the yoke; and a coil disposed to oppose the magnet. The yoke includes a yoke attachment extending in the vertical direction and connected to the sample holding member. The yoke attachment portion is fixed on a circumference that is a node of the primary nodal circular vibration mode of the sample holding member.

### TECHNICAL FIELD

The present invention relates to a sample surface inspection apparatus that inspects presence or absence of a foreign matter or a defect adhering to a surface of a sample such as a wafer or glass substrate.

### BACKGROUND ART

In a manufacturing process of semiconductor devices, a surface inspection apparatus is used to inspect presence or absence of a foreign matter or a defect on a surface of a sample such as a wafer. The surface inspection apparatus irradiates a surface of a rotating disk-shaped sample with a laser light and moves the sample in a radial direction of the sample to inspect the entire surface of the sample. In a case where the foreign matter or the defect is present on the surface of the sample, the irradiated laser light scatters. A detection optical system receives the scattered light to detect the foreign matter or the defect, and specifies the position of the foreign matter or the defect on the sample from a rotation angle and a radial position of the sample.

For miniaturization of semiconductor devices, surface inspection apparatuses are required to improve detection sensitivity of the foreign matter and the defect. Progress is being made in achieving reduction in wavelength of the laser light to improve the detection sensitivity. As the wavelength of the laser light is shorter, a focal depth of an optical system is lower. Therefore, in a case where the height position of the surface of the sample fluctuates during the inspection, the height position of the surface of the sample may deviate from an allowable focal range of the optical system. As a result, there is a concern that a decrease in detection sensitivity and a shift in the detection position may occur.

In order to bring the height position of the sample within the allowable focal range of the optical system, it is conceivable to rotate the sample and drive the sample in a focus direction perpendicular to the surface of the sample to correct a focus position of the sample with high accuracy. In such a case, a driving force in the focus direction acts on the sample and a sample holding member that holds the sample. Therefore, there is a concern that the vibration of the sample and the sample holding member excited by the driving force may occur. Accordingly, in order to perform a highly accurate inspection by correcting the focus position of the sample, it is necessary to reduce the vibration of the sample and the sample holding member.

Therefore, for example, PTL 1 describes the following configuration. A vibration waveform is formed to have a phase opposite to a phase of a vibration waveform detected by a vibration detection device that detects the vibration of the sample, the vibration waveform is amplified to obtain an output waveform and vibrate a vibration plate with the output waveform, and sound waves are emitted toward the surface of the sample. Thereby, the vibration of the sample is suppressed.

### CITATION LIST

### Patent Literature

PTL 1: JP2013-131672A

### SUMMARY OF INVENTION

### Technical Problem

PTL 1 describes a configuration in which vibration at a local position on the sample is detected and the sound waves are emitted toward the position.

However, since there are multiple vibration modes for the sample, some of target vibration modes may not be suppressed by only emitting the sound waves locally.

Therefore, the present invention provides a sample surface inspection apparatus capable of performing a highly accurate inspection while suppressing vibration of a sample and a sample holding member.

### Solution to Problem

In order to solve the above-mentioned problem, a sample surface inspection apparatus according to an embodiment of the present invention include, at least: a sample holding member that holds a sample; a spindle motor that rotates the sample holding member; a turntable that is fixed to the spindle motor and rotated by an action of the spindle motor; and a focus driving mechanism that generates a driving force for displacing the sample holding member in a focus direction which is a height direction with respect to the turntable. The focus driving mechanism includes a plurality of supporting members, each of which has one end fixed to the sample holding member and the other end fixed to the turntable, the plurality of supporting members supporting the sample holding member so as to be displaceable in the focus direction, which is the height direction, with respect to the turntable, a yoke, a magnet that is fixed to the yoke, and a coil that is disposed opposite to the magnet. The yoke has a yoke mounting portion that extends in a vertical direction and that is connected to the sample holding member, and the yoke mounting portion is fixed on a circumference that is a node of a primary nodal circular vibration mode of the sample holding member.

### Advantageous Effects of Invention

According to the embodiment of the present invention, it is possible to provide a sample surface inspection apparatus capable of performing a highly accurate inspection while suppressing vibration of a sample and a Sample holding member.

Specifically, it is possible to reduce the variation in amount of displacement in a case where the sample is driven in the focus direction, and also to reduce the amplitude of the vibration of the sample holding member. As a result, it is possible to perform highly accurate correction for the focus position of the sample.

Problems, configurations, and effects other than those described above will be clarified by the following description of the embodiments.

### BRIEF DESCRIPTION OF DRAWINGS

FIG. 1 is an overall schematic configuration diagram of a sample surface inspection apparatus according to a first embodiment of the present invention.

FIG. 2 is an external view illustrating a focus driving mechanism included in the sample surface inspection apparatus illustrated in FIG. 1.

FIG. 3 is an exploded view of the focus driving mechanism illustrated in FIG. 2.

FIG. 4 is a diagram illustrating a sample holding member, supporting members, and a yoke included in the focus driving mechanism illustrated in FIG. 2.

FIG. 5 is a top view illustrating the sample holding member, the supporting members, and the yoke included in the focus driving mechanism illustrated in FIG. 2.

FIG. 6A is a diagram illustrating a state where the sample holding member included in the focus driving mechanism illustrated in FIG. 2 is not vibrating.

FIG. 6B is a diagram illustrating a vibration mode of the sample holding member included in the focus driving mechanism illustrated in FIG. 2, the diagram illustrating a state where a center of the sample holding member is deformed to be convex.

FIG. 6C is a diagram illustrating a vibration mode of the sample holding member included in the focus driving mechanism illustrated in FIG. 2, the diagram illustrating a state where the center of the sample holding member is deformed to be concave.

FIG. 7 is a diagram illustrating vibration characteristics of the sample holding member using the focus driving mechanism according to the first embodiment of the present invention, the diagram illustrating a case where a position for fixation of the yoke mounting portion to the sample holding member is 0.7 times a radius R of the sample holding member.

FIG. 8A is a diagram illustrating vibration characteristics of the sample holding member using the focus driving mechanism according to the first embodiment of the present invention, the diagram illustrating a case where the position for fixation of the yoke mounting portion to the sample holding member is 0.6 times the radius R of the sample holding member.

FIG. 8B is a diagram illustrating vibration characteristics of the sample holding member using the focus driving mechanism according to the first embodiment of the present invention, the diagram illustrating a case where the position for fixation of the yoke mounting portion to the sample holding member is 0.8 times the radius R of the sample holding member.

FIG. 9 is an external view of a focus driving mechanism included in a sample surface inspection apparatus according to a second embodiment of the present invention.

FIG. 10 is an exploded view of the focus driving mechanism illustrated in FIG. 9.

FIG. 11 is a top view illustrating the sample holding member, the supporting members, the damping members, and the yoke included in the focus driving mechanism illustrated in FIG. 9.

FIG. 12 is a diagram illustrating vibration characteristics o f the sample holding member using the focus driving mechanism according to the second embodiment of the present invention, the diagram illustrating a case where a position for fixation of the yoke mounting portion to the sample holding member is 0.7 times a radius R of the sample holding member.

FIG. 13A is a diagram illustrating vibration characteristics of the sample holding member using the focus driving mechanism according to the second embodiment of the present invention, the diagram illustrating a case where the position for fixation of the yoke mounting portion to the sample holding member is 0.6 times the radius R of the sample holding member.

FIG. 13B is a diagram illustrating vibration characteristics of the sample holding member using the focus driving mechanism according to the second embodiment of the present invention, the diagram illustrating a case where the position for fixation of the yoke mounting portion to the sample holding member is 0.8 times the radius R of the sample holding member.

### DESCRIPTION OF EMBODIMENTS

Hereinafter, embodiments of the present invention will be described, with reference to the drawings.

### First Embodiment

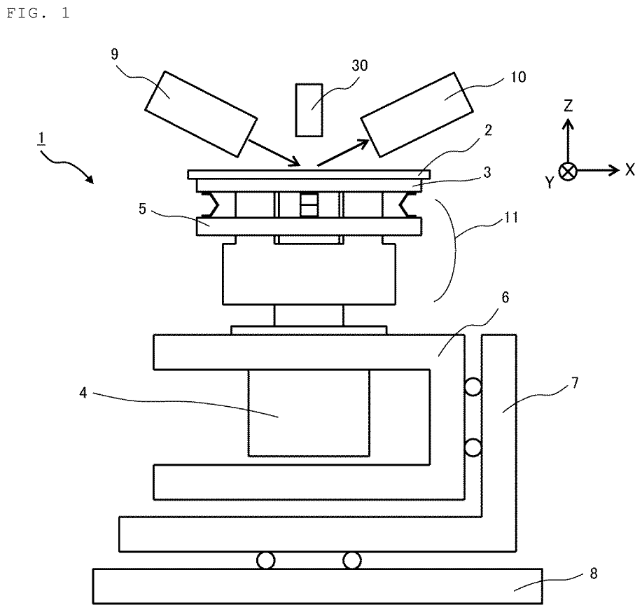

FIG. 1 is an overall schematic configuration diagram of a sample surface inspection apparatus according to a first embodiment of the present invention. The sample surface inspection apparatus 1 includes a sample holding member 3, a spindle motor 4, a turntable 5, a frame 6, a vertical driving stage 7, a horizontal driving stage 8, an illumination optical system 9, a detection optical system 10, a focus driving mechanism 11, and a sample height position sensor 30. The sample holding member 3 has a disk shape and holds the sample 2. The sample 2 is, for example, a glass substrate or a disk-shaped wafer. A direction perpendicular to the surface of the sample 2, which is the height direction of the sample surface inspection apparatus 1, is set as a focus direction (Z direction), and two directions perpendicular to the focus direction are set as the X direction and the Y direction.

The spindle motor 4 is fixed to the frame 6. The turntable 5 is fixed to one end of the spindle motor 4. The focus driving mechanism 11 is a mechanism that displaces the sample 2 and the sample holding member 3 in the focus direction with respect to the turntable 5. Details of the focus driving mechanism 11 will be described later. The spindle motor 4 rotates the turntable 5 around the Z axis, and the sample 2 and the sample holding member 3 rotate around the Z axis via the focus driving mechanism 11.

The vertical driving stage 7 moves the frame 6 in the focus direction (Z direction) such that a position of the surface of the sample 2 is within a predetermined height range. The vertical driving stage 7 moves the frame 6 in the focus direction, thereby moving the sample 2 and the Sample holding member 3 in the focus direction via the spindle motor 4, the turntable 5, and the focus driving mechanism 11. The horizontal driving stage 8 moves the vertical driving stage 7 in one radial direction of the sample holding member 3 (the X direction in FIG. 1). The horizontal driving stage 8 moves the vertical driving stage 7 in the X direction, thereby moving the sample 2 and the sample holding member 3 in the X direction via the frame 6, the spindle motor 4, the turntable 5, and the focus driving mechanism 11.

The illumination optical system 9 irradiates the surface of the sample 2 with laser light. In a case where there is a foreign matter or a defect on the surface of the sample 2, the laser light, with which the surface of the sample 2 is irradiated, is scattered on the surface, and scattered light is generated. The detection optical system 10 receives the scattered light generated on the surface of the sample 2. A processing device (not illustrated in the drawing) is connected to the detection optical system 10. The processing device detects presence or absence of the foreign matter or the defect on the surface of the sample 2 from a signal of the scattered light received by the detection optical system 10, and specifies the position of the foreign matter or the defect from a rotation angle and a radial position of the sample holding member 3.

The sample surface inspection apparatus 1 scans the entire surface of the sample 2 by moving the sample holding member 3 in the radial direction (X direction) through the horizontal driving stage 8 while rotating the sample holding member 3 around the Z axis through the spindle motor 4.

The vertical driving stage 7 is a mechanism that adjusts an average-height position (position in the focus direction) of the surface of the sample 2. A speed at which the vertical driving stage 7 moves the frame 6 in the focus direction, that is, a speed at which the sample holding member 3 moves in the focus direction by the vertical stage 7 is slower than a rotation speed of the sample holding member 3 by the spindle motor 4. Therefore, it is difficult for the vertical driving stage 7 to correct the positional fluctuation of the sample 2 in the focus direction during the rotation. In order to inspect the sample 2 with high accuracy, it is necessary to adjust the height position of the sample holding member 3 (that is, the surface of the sample 2) in accordance with the positional fluctuation of the sample 2 in the focus direction during the rotation of the sample 2. The sample surface inspection apparatus 1 according to the present embodiment includes the focus driving mechanism 11 capable of adjusting the height position of the sample holding member 3 during the rotation.

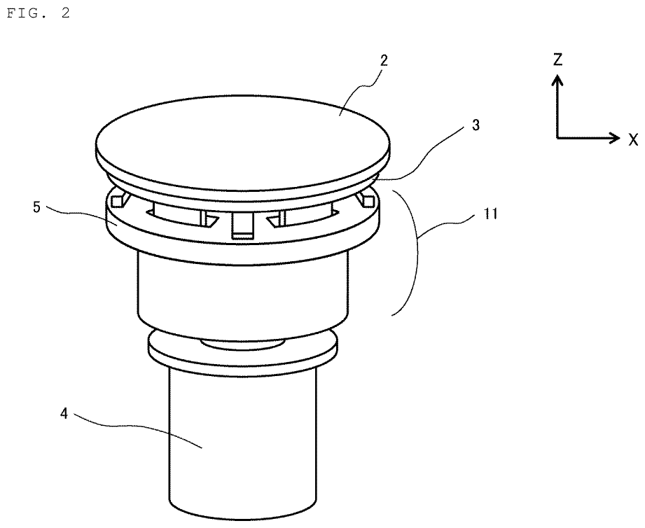

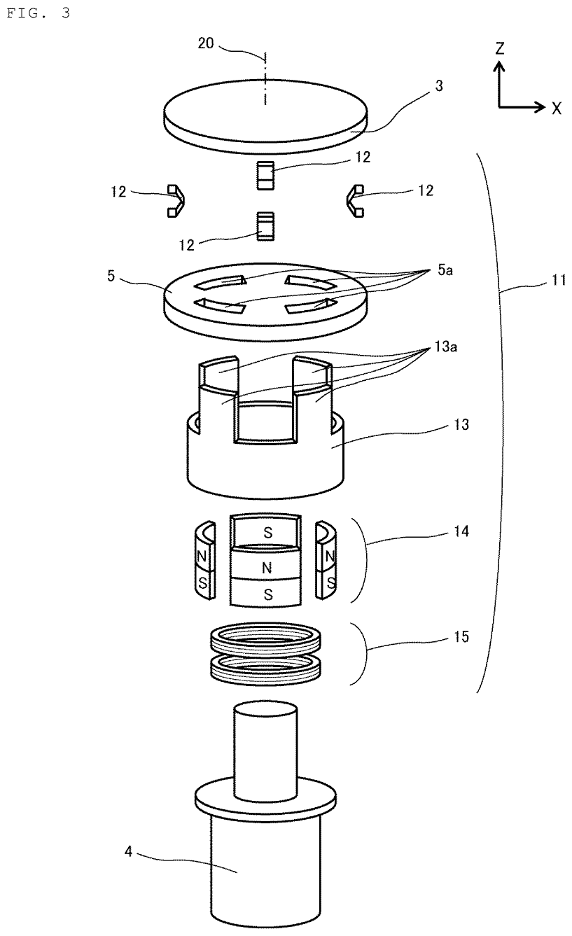

FIG. 2 is an external view illustrating the focus driving mechanism included in the sample surface inspection apparatus illustrated in FIG. 1. FIG. 3 is an exploded view of the focus driving mechanism illustrated in FIG. 2. FIG. 2 illustrates the sample 2, the sample holding member 3, the spindle motor 4, the turntable 5, and the focus driving mechanism 11. FIG. 3 illustrates an exploded view of the sample holding member 3, the spindle motor 4, the turntable 5, and the focus driving mechanism 11. FIG. 3 illustrates a central axis 20 of the sample holding member 3 that is parallel to the Z axis. The central axis 20 of the sample holding member 3 coincides with the axis of rotation of the spindle motor 4. The turntable 5 is fixed to one end of the spindle motor 4 and rotates around the Z axis through the spindle motor 4.

The focus driving mechanism 11 includes supporting members 12, a yoke 13, a magnet 14, and a coil 15.

Each supporting member 12 is provided between the sample holding member 3 and the turntable 5, and has one end fixed to the sample holding member 3 and the other end fixed to the turntable 5. The supporting member 12 is made of an elastic body such as metal, and supports the sample 2 and the sample holding member 3 so as to be displaceable in the focus direction with respect to the turntable 5. Here, the elastic body such as metal is realized by, for example, a leaf spring or a coil spring. A shape of the elastic body such as metal may have a shape having a plurality of bent portions or may have a curved shape. The supporting member 12 is disposed on a circumference centered on the central axis 20 of the sample holding member 3 (the axis of rotation of the spindle motor 4). FIG. 3 illustrates a configuration having four supporting members 12. However, the number of supporting members 12 is not limited thereto, and may be a desired number such as six or eight.

The sample holding member 3 is fixed to one end of the supporting member 12, the other end of the supporting member 12 is fixed to the turntable 5, and the turntable 5 is fixed to the spindle motor 4. Therefore, in a case where the spindle motor 4 rotates the turntable 5, the sample holding member 3 rotates via the supporting member 12 together with the rotation of the turntable 5. Thereby, the sample 2 held by the sample holding member 3 rotates around the Z axis.

The yoke 13 has a cylindrical portion, and includes a yoke mounting portion 13a, which is connected to the sample holding member 3, at the top of the cylindrical portion. Although FIG. 3 illustrates a configuration having the four yoke mounting portions 13a, the number of yoke mounting portions 13a is not limited thereto. The yoke mounting portion 13a extending vertically from the cylindrical portion of the yoke 13 passes through an opening portion 5a provided in the turntable 5 and is fixed to the sample holding member 3.

The magnet 14 is configured to have two stages in the focus direction, has an arc shape as viewed from the focus direction, and is fixed to an inner surface of the cylindrical portion of the yoke 13 at intervals along a direction of circumference. The magnet 14 is magnetized in the radial direction of the sample holding member 3. £ In FIG. 3, a first magnet in the upper stage in the focus direction has an N pole on a side coming into contact with the yoke 13 and an S pole on a side opposite to the surface coming into contact with the yoke 13, and a second magnet in the lower stage in the focus direction has an S pole on the side coming into contact with the yoke 13 and an N pole on a side opposite to the surface coming into contact with the yoke 13. Although FIG. 3 illustrates a configuration having four groups of magnets 14 in the direction o f circumference, but the number of magnets 14 in the direction of circumference is not limited thereto. Polarities of the magnets 14 may be opposite to the polarities mentioned above.

The coil 15 has an annular shape, and two coils are disposed in the focus direction facing the two-stage magnets 14. The coils 15 are fixed to a fixing member which is not illustrated in the drawing.

By passing a current through the coil 15, an electromagnetic force acts on the magnet 14 and the coil 15 due to interaction with the magnet 14. In such a case, the coil 15 is fixed to the fixing member (not illustrated in the drawing) and does not displace. Further, the turntable 5 is fixed to the spindle motor 4, and the spindle motor 4 is fixed to the frame 6. Therefore, the turntable 5 does not displace in the focus direction. Accordingly, the electromagnetic force acting on the magnet 14 becomes a driving force in the focus direction, and the magnet 14, the yoke 13, and the sample holding member 3 are displaced as a single movable part in the focus direction. The sample 2 held by the sample holding member 3 is displaced in the focus direction together with the displacement of the Sample holding member 3.

In such a manner, the spindle motor 4 rotates the sample holding member 3 and the sample 2 while the focus driving mechanism 11 drives the sample holding member 3 and the sample 2 in the focus direction.

Here, a method of adjusting the height position of the sample 2 will be described. The sample surface inspection apparatus 1 includes a sample height position sensor 30 (refer to FIG. 1) that detects the height of the surface of the sample 2. The sample height position sensor 30 is, for example, an optical or ultrasonic displacement sensor. The focus driving mechanism 11 drives the sample holding member 3 and the sample 2 in the focus direction, on the basis of the height position of the sample 2 detected by the sample height position sensor 30, thereby adjusting the height position of the surface of the sample 2 such that the height position is within the allowable focus range of the detection optical system 10. In such a manner, the sample surface inspection apparatus 1 is able to adjust the height position of the sample 2.

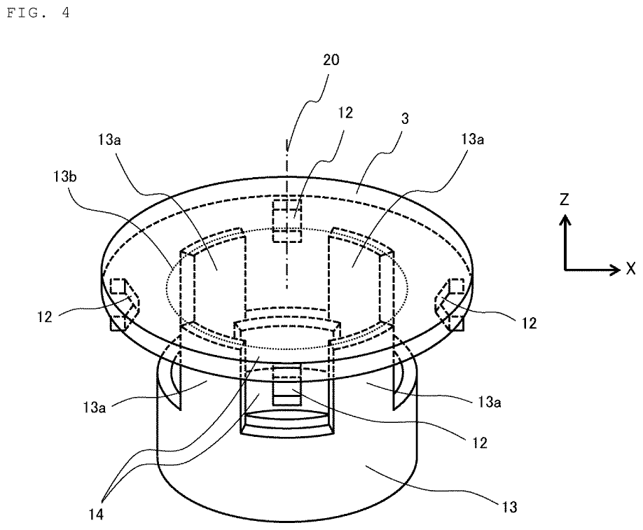

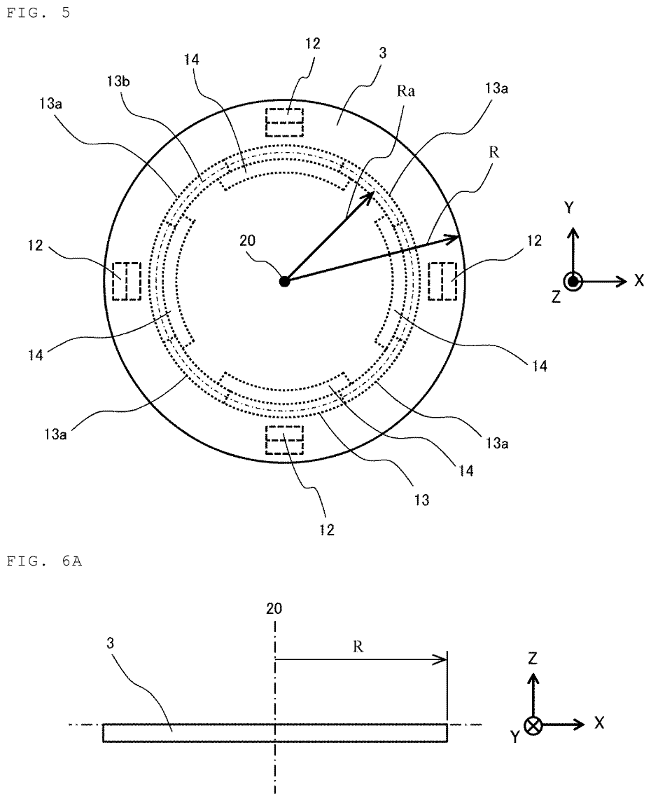

FIG. 4 is a diagram illustrating the sample holding member, the supporting members, and the yoke included in the focus driving mechanism illustrated in FIG. 2. FIG. 4 illustrates a perspective view of the sample holding member 3, supporting members 12, and yoke 13. FIG. 5 is a top view illustrating the sample holding member, the supporting members, and the yoke included in the focus driving mechanism illustrated in FIG. 2. In FIG. 4, the lower end (other end) of each supporting member 12 is fixed to the turntable 5 (not illustrated in the drawing). The yoke mounting portion 13a extending vertically from the cylindrical portion of the yoke 13 has an arc shape as viewed from the focus direction and is fixed on the circumference centered on the central axis 20 (the axis of rotation of the spindle motor 4) of the sample holding member 3. That is, the yoke mounting portion 13a is fixed to a position 13b for fixation of the yoke mounting portion to the sample holding member. As illustrated in FIG. 5, a radius Ra of the circumference 13b, on which the yoke mounting portion 13a is fixed to the sample holding member 3, is in a range of 0.6 to 0.8 times the radius R of the sample holding member 3. A description will be hereinafter given of a case where the vibration of the sample holding member 3 can be reduced by fixing the yoke mounting portion 13a to the sample holding member 3 in such a manner.

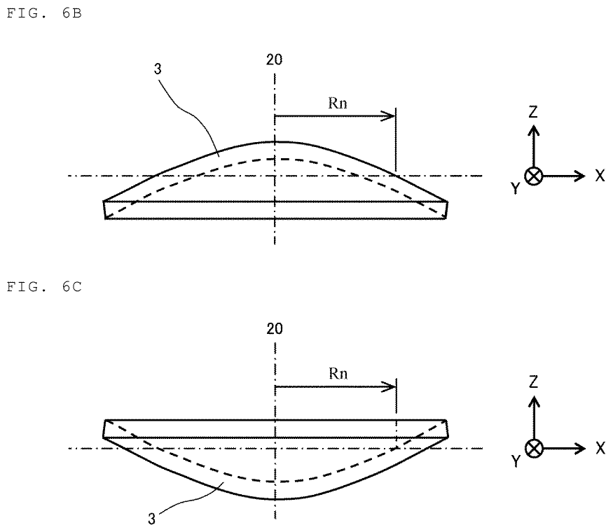

FIG. 6A is a diagram illustrating a state where the sample holding member included in the focus driving mechanism illustrated in FIG. 2 is not vibrating. FIG. 6B is a diagram illustrating the vibration mode of the sample holding member included in the focus driving mechanism illustrated in FIG. 2, the diagram illustrating a state where a center of the sample holding member is deformed to be convex. FIG. 6C is a diagram illustrating a vibration mode of the sample holding member included in the focus driving mechanism illustrated in FIG. 2, the diagram illustrating a state where the center of the sample holding member is deformed to be concave. FIGS. 6A to 6C are diagrams illustrating a primary nodal circular vibration mode, which is a concern as a vibration mode of the sample holding member 3, and are diagrams of the sample holding member 3 viewed from a direction perpendicular to the focus direction. As illustrated in FIG. 6A, in a state where the sample holding member 3 is not vibrating, the surface of the sample holding member 3 is flat and is present at a position indicated by the chain line. The primary nodal circular vibration mode is a vibration mode in which the center of the disk is deformed to be convex or the center of the disk is deformed to be concave, in which one node position (a position at which the surface of the sample holding member 3 intersects with the chain line) appears in an annular shape. FIG. 6B illustrates a state where the center is deformed to a convex shape. FIG. 6C illustrates a state where the center is deformed to a concave shape. In FIG. 6B and FIG. 6C, a radius of the circle, which is the node of this primary nodal circular vibration mode, is Rn.

The driving force in the focus direction acts on the sample holding member 3 from the magnet 14 via the yoke 3 and the yoke mounting portion 13a. Accordingly, the driving force in the focus direction acts on the sample holding member 3 at the position for fixation of the yoke mounting portion 13a. In such a case, by setting the position for fixation of the yoke mounting portion 13a to the sample holding member 3 on the circumference that is the node of the primary nodal circular vibration mode of the sample holding member 3, it is possible to prevent the primary nodal circular vibration mode from being excited.

In a case of the sample holding member 3 having the disk shape, the radius Rn as a node of the primary nodal circular vibration mode is about 0.7 times the radius R of the sample holding member 3. In the present embodiment, by setting the position for fixation of the yoke mounting portion 13a to the sample holding member 3 in the range of 0.6 to 0.8 times the radius R of the sample holding member 3, which is close to the node of the primary nodal circular vibration mode, the amplitude of the primary nodal circular vibration mode can be reduced.

Further, in the present embodiment, as illustrated in FIGS. 4 and 5, the supporting members 12 are disposed on the outer circumferential side of the position for fixation of the yoke mounting portion 13a to the sample holding member 3. Since the supporting members 12 are disposed in such a manner, it is possible to heighten the resonant frequency of the translational mode in which the sample holding member 3 and the sample 2 operate in the focus direction due to the driving force in the focus direction.

Furthermore, the supporting members 12 are disposed at equal intervals in the direction of circumference centered on the central axis 20 of the sample holding member 3. Since the supporting members 12 are disposed at equal intervals in the direction of circumference, the rigidities against the displacements of the sample holding member 3 and the sample 2 in the focus direction can be evenly distributed.

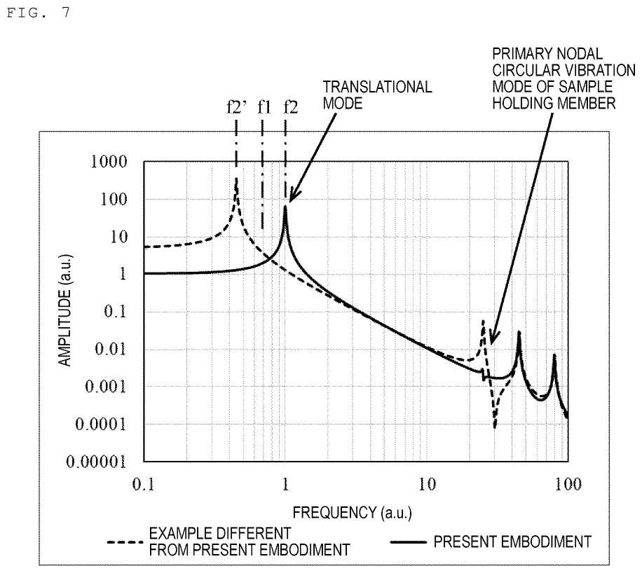

FIG. 7 is a diagram illustrating vibration characteristics of the sample holding member using the focus driving mechanism according to the present embodiment, the diagram illustrating a case where the position for fixation of the yoke mounting portion to the sample holding member is 0.7 times the radius R of the sample holding member. In FIG. 7, the horizontal axis of the graph indicates the frequency, and the vertical axis indicates the amplitude of the displacement in the focus direction. The solid line indicates characteristics in the present embodiment, and the broken line indicates characteristics as a comparative example in a case different from the present embodiment (in a case where the rigidity of the supporting member is low). The frequency on the horizontal axis indicates the resonant frequency of the translational mode of the characteristics in the present embodiment as 1, and the amplitude on the vertical axis indicates the value in the low frequency region of the characteristics in the present embodiment as 1.

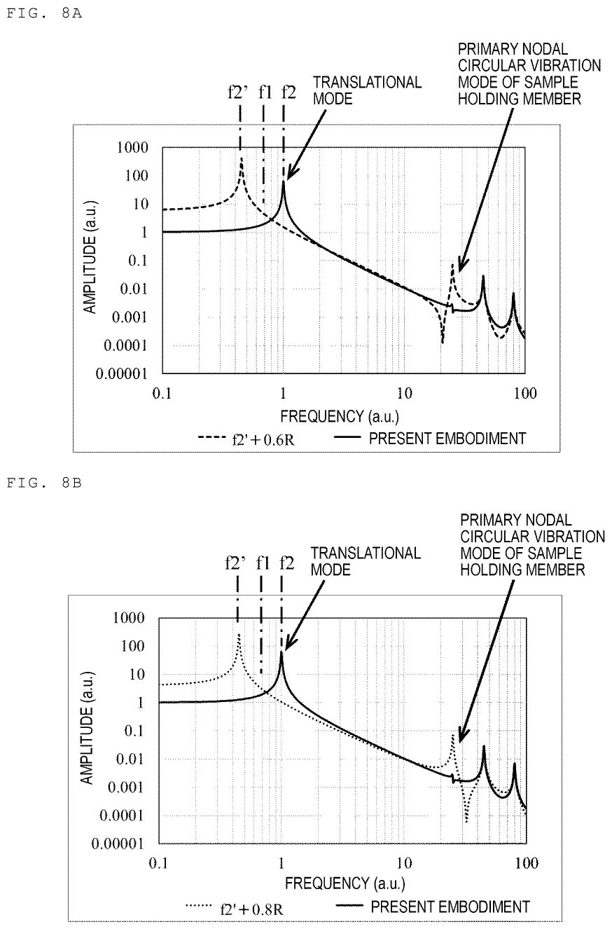

FIG. 8A is a diagram illustrating vibration characteristics of 41 the sample holding member using the focus driving mechanism according to the present embodiment, the diagram illustrating a case where the position for fixation of the yoke mounting portion to the sample holding member is 0.6 times the radius R of the sample holding member. FIG. 8B is a diagram illustrating vibration characteristics of the sample holding member using the focus driving mechanism according to the present embodiment, the diagram illustrating a case where the position for fixation of the yoke mounting portion to the sample holding member is 0.8 times the radius R of the sample holding member. Further, FIG. 8B is a diagram illustrating vibration characteristics of the sample holding member using the focus driving mechanism according to the present embodiment, the diagram illustrating a case where the position for fixation of the yoke mounting portion to the sample holding member is 0.8 times the radius R of the sample holding member. FIG. 8A illustrates a case where the resonant frequency f2′ of the translational mode is lower than the maximum value of the rotation frequency of the sample holding member 3, and the position for fixation of the yoke mounting portion 13a to the sample holding member 3 is 0.6 times the radius R of the sample holding member 3, as characteristics in a case different from the present embodiment. FIG. 8B illustrates a case where the resonant frequency f2′ of the translational mode is lower than the maximum value of the rotation frequency of the sample holding member 3, and the position for fixation of the yoke mounting portion 13a to the sample holding member 3 is 0.8 times the radius R of the sample holding member 3, as characteristics in a case different from the present embodiment.

The resonant frequency of the translational mode is determined by the rigidity of the supporting member 12 and the mass of the movable part (magnet 14, yoke 13, and sample holding member 3). In the present embodiment, the resonant frequency f2 of the translational mode is set to a value higher than the maximum value f1 of the rotation frequency of the sample holding member 3 by the spindle motor 4 by setting the rigidity of the supporting member 12 and the mass of the movable part. Since the rotation frequency of the sample holding member 3 is also the rotation frequency of the sample 2, the maximum value f1 indicates the upper limit of the rotation frequency of the sample 2 in the sample surface inspection apparatus 1.

Generally, the amplitude increases rapidly near the resonant frequency, and variation in amplitude tends to occur. Therefore, as in the characteristics in a case different from the present embodiment, in a case where the resonant frequency f2′ of the translational mode is lower than the maximum value f1 of the rotation frequency of the sample holding member 3, it is difficult to perform stable focus driving near the resonant frequency f2′. In contrast, in the present embodiment, the resonant frequency f2 of the translational mode is made higher than the maximum value f1 of the rotation frequency of the sample holding member 3. Therefore, the increase in amplitude can be suppressed within the range of the rotation frequency of the sample holding member 3. As a result, it is possible to drive stable focusing.

Further, in the present embodiment, the position for fixation of the yoke mounting portion 13a to the sample holding member 3 is set in the range of 0.6 to 0.8 times the radius R of the sample holding member 3. Therefore, the amplitude of the primary nodal circular vibration mode of the sample holding member 3 indicated by the broken lines in FIGS. 7, 8A, and 8B can be reduced to the characteristics indicated by the solid lines. Thereby, the focus driving mechanism 11 is able to stably adjust the height position of the sample 2 throughout a wide frequency range.

In such a manner, it is possible to reduce the variation in amplitude in a case where the focus driving mechanism 11 drives the sample holding member 3 and the Sample 2 in the focus direction, and it is possible to reduce the amplitude in the vibration mode of the sample holding member 3.

According to the present embodiment described above, it is possible to provide a sample surface inspection apparatus capable of performing a highly accurate inspection while suppressing vibration of a sample and a sample holding member.

Further, it is possible to reduce the variation in amount of displacement in a case where the sample is driven in the focus direction, and it is also possible to reduce the amplitude of the vibration of the sample holding member. As a result, it is possible to perform highly accurate correction for the focus position of the sample.

### Second Embodiment

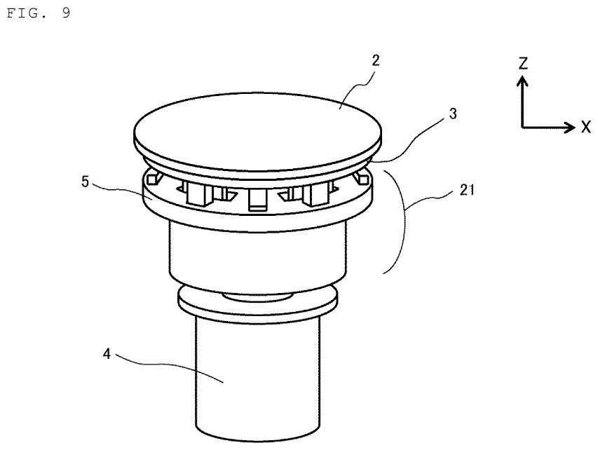

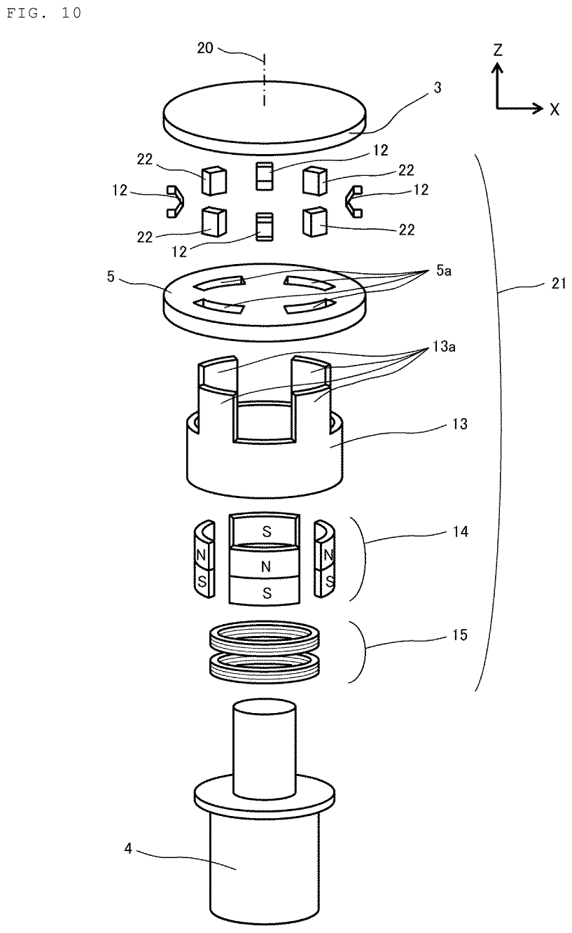

FIG. 9 is an external view illustrating a focus driving mechanism included in a sample surface inspection apparatus according to a second embodiment of the present invention. FIG. 10 is an exploded view illustrating the focus driving mechanism illustrated in FIG. 9. The focus driving mechanism according to the present embodiment differs from the above-mentioned first embodiment in that the focus driving mechanism further includes a damping member 22. The same components as the components in the first embodiment are represented by the same reference numerals and signs, and a description that overlaps with the first embodiment will not be repeated.

As illustrated in FIGS. 9 and 10, a focus driving mechanism 21 according to the present embodiment includes supporting members 12, damping members 22, a yoke 13, a magnet 14, and a coil 15. Each damping member 22 is provided between the sample holding member 3 and the turntable 5, and has one end connected to the sample holding member 3 and the other end connected to the turntable 5. The damping member 22 includes a polymer compound, a viscoelastic body, and the like, and is a member that reduces vibration and/or impact. The damping member 22 is disposed on the circumference centered on the central axis 20 of the sample holding member 3 (the axis of rotation of the spindle motor 4). FIG. 9 illustrates a configuration having four damping members 22. However, the number of damping members 22 is not limited thereto.

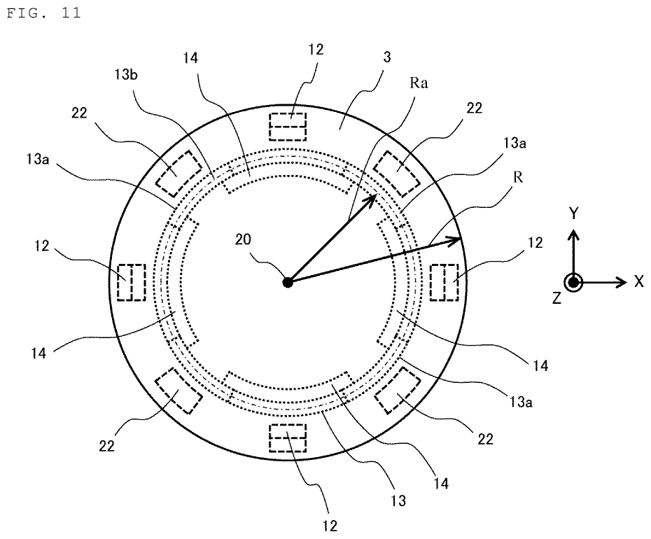

FIG. 11 is a top view illustrating the sample holding member, the supporting members, the damping members, and the yoke included in the focus driving mechanism illustrated in FIG. 9. As illustrated in FIG. 11, the damping members 22 are disposed on the outer circumferential side of the position 13b for fixation of the yoke mounting portion 13a to the sample holding member 3. In a case where the sample holding member 3 is tilted when displaced in the focus direction, the displacement is large at the outer circumferential edge of the sample holding member 3. Since the damping members 22 are disposed on the outer circumferential side on which the displacement is large, it is possible to reduce the effect of the tilt in a case where the sample holding member 3 is displaced in the focus direction.

Further, the damping members 22 are also disposed at equal intervals in the direction of circumference centered on the central axis 20 of the sample holding member 3. Since the damping members 22 are disposed at equal intervals in the direction of circumference, the damping effects against the displacements of the sample holding member 3 and the sample 2 in the focus direction can be evenly distributed.

Furthermore, the supporting members 12 and the damping members 22 are alternately disposed along the direction of circumference centered on the central axis 20 of the sample holding member 3. Thereby, the rigidities 44 the supporting members 12 and the damping effects of the damping members 22 against the displacements in the focus direction can be evenly applied, and the variations in the displacements of the sample holding member 3 and the sample 2 in the focus direction can be further reduced.

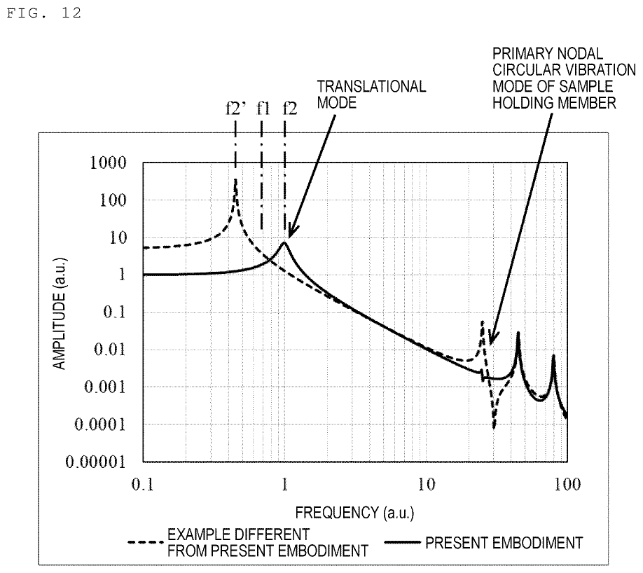

FIG. 12 is a diagram illustrating vibration characteristics of the sample holding member using the focus driving mechanism according to the second embodiment of the present invention, the diagram illustrating a case where the position for fixation of the yoke mounting portion to the sample holding member is 0.7 times the radius R of the sample holding member. In FIG. 12, the horizontal axis of the graph indicates the frequency, and the vertical axis indicates the amplitude of the displacement in the focus direction. The solid line indicates characteristics in the present embodiment, and the broken line indicates characteristics different from the present embodiment (in a case where the rigidity of the supporting member is low). The frequency on the horizontal axis indicates the resonant frequency of the translational mode of the characteristics in the present embodiment as 1, and the amplitude on the vertical axis indicates the value in the low frequency region of the characteristics in the present embodiment as 1.

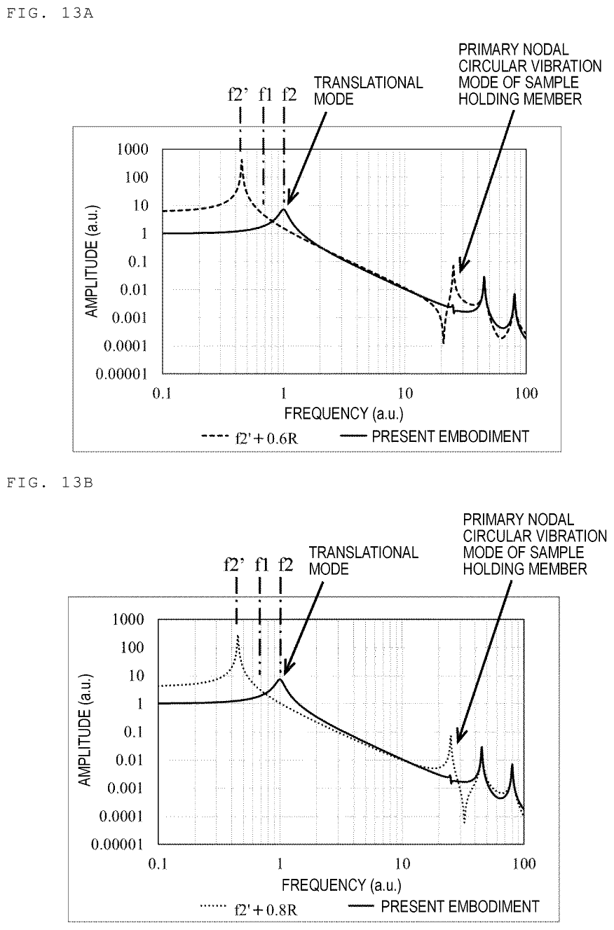

FIG. 13A is a diagram illustrating vibration characteristics of the sample holding member using the focus driving mechanism according to the present embodiment, the diagram illustrating a case where the position for fixation of the yoke mounting portion to the sample holding member is 0.6 times the radius R of the sample holding member. FIG. 13B is a diagram illustrating vibration characteristics of the sample holding member using the focus driving mechanism according to the present embodiment, the diagram illustrating a case where the position for fixation of the yoke mounting portion to the sample holding member is 0.8 times the radius R of the sample holding member.

FIG. 13A illustrates a case where the resonant frequency f2′ of the translational mode is lower than the maximum value of the rotation frequency of the sample holding member 3, the damping members 22 are not disposed, and the position for fixation of the yoke mounting portion 13a to the sample holding member 3 is 0.6 times the radius R of the sample holding member 3, as characteristics indicated by the broken line in a case different from the present embodiment.

FIG. 13B illustrates a case where the resonant frequency f2′ of the translational mode is lower than the maximum value of the rotation frequency of the sample holding member 3, the damping members 22 are not disposed, and the position for fixation of the yoke mounting portion 13a to the sample holding member 3 is 0.8 times the radius R of the sample holding member 3, as characteristics in a case different from the present embodiment.

In the present embodiment, as in the first embodiment, the resonant frequency f2 of the translational mode is set to a value higher than the maximum value f1 of the rotation frequency of the sample holding member 3 by the spindle motor 4 and the position 13b for fixation of the yoke mounting portion 13a to the sample holding member 3 is set in the range of 0.6 to 0.8 times the radius R of the sample holding member 3. In such a manner, it is possible to reduce the variation in amplitude of the translational mode during driving in the focus direction, and it is possible to reduce the amplitude in the vibration mode of the sample holding member 3.

Further, in the present embodiment, since the damping members 22 are disposed, the amplitude at the resonant frequency of the translational mode can be reduced to be lower than the amplitude in the first embodiment. Thereby, it is possible to further reduce the variation in amplitude of the translational mode. As a result, it is possible to realize a sample surface inspection apparatus capable of performing a highly accurate inspection while suppressing vibration of the sample 2 and the sample holding member 3.

As described above, according to the present embodiment, in addition to the effects of the above-mentioned first embodiment, the amplitude at the resonant frequency of the translational mode can be reduced to be lower than the amplitude in the first embodiment since the damping members 22 are disposed. Thereby, it is possible to further reduce the variation in amplitude of the translational mode.

It should be noted that the present invention is not limited to the above-mentioned embodiment and further includes various modification examples. For example, the above-mentioned embodiments have been described in detail to make the invention easier to understand, and are not necessarily limited to those having all of the configurations described. Further, it is possible to replace a part of the configuration of a certain embodiment with the configuration of another embodiment, and it is also possible to add the configuration of another embodiment to the configuration of a certain embodiment.

### REFERENCE SIGNS LIST

1: surface inspection apparatus
2: sample
3: sample holding member
4: spindle motor
5: turntable
5a: opening portion
6: frame
7: vertical driving stage
8: horizontal driving stage
9: illumination optical system
10: detection optical system
11, 21: focus driving mechanism
12: Supporting member
13: yoke
13a: yoke mounting portion
13b: position for fixation of yoke mounting portion to sample holding member
14: magnet
15: coil
20: central axis of sample holding member
22: damping member
30: sample height position sensor

1. A sample surface inspection apparatus comprising, at least:
a sample holding member that holds a sample;
a spindle motor that rotates the sample holding member;
a turntable that is fixed to the spindle motor and rotated by an action of the spindle motor; and
a focus driving mechanism that generates a driving force for displacing the sample holding member in a focus direction which is a height direction with respect to the turntable,
wherein the focus driving mechanism includes
a plurality of supporting members, each of which has one end fixed to the sample holding member and the other end fixed to the turntable, the plurality of supporting members supporting the sample holding member so as to be displaceable in the focus direction, which is the height direction, with respect to the turntable,
a yoke,
a magnet that is fixed to the yoke, and
a coil that is disposed opposite to the magnet, and
wherein the yoke has a yoke mounting portion that extends in a vertical direction and that is connected to the sample holding member, and the yoke mounting portion is fixed on a circumference that is a node of a primary nodal circular vibration mode of the sample holding member.

2. The sample surface inspection apparatus according to claim 1,
wherein the yoke mounting portion is positioned on a circumference centered on an axis of rotation of the spindle motor.

3. The sample surface inspection apparatus according to claim 2,
wherein a position, at which the yoke mounting portion is connected to the sample holding member, is within a range of 0.6 to 0.8 times a radius of the sample holding member.

4. The sample surface inspection apparatus according to claim 2,
wherein a resonant frequency of a translational mode, in which the sample holding member operates in the focus direction, is higher than a maximum value of a rotation frequency of the sample holding member rotated by the action of the spindle motor.

5. The sample surface inspection apparatus according to claim 3,
wherein the supporting members are positioned on the circumference centered on the axis of rotation of the spindle motor, on an outer circumferential side of a position at which the yoke mounting portion is fixed to the sample holding member.

6. The sample surface inspection apparatus according to claim 4,
wherein the supporting members are positioned on the circumference centered on the axis of rotation of the spindle motor, on an outer circumferential side of a position at which the yoke mounting portion is fixed to the sample holding member.

7. The sample surface inspection apparatus according to claim 5,
wherein the plurality of supporting members are disposed at equal intervals in a direction of the circumference centered on the axis of rotation of the spindle motor.

8. The sample surface inspection apparatus according to claim 6,
wherein the plurality o f supporting members are disposed at equal intervals in a direction of the circumference centered on the axis of rotation of the spindle motor.

9. The sample surface inspection apparatus according to claim 7, further comprising:
a plurality of damping members each of which has one end connected to the sample holding member and the other end connected to the turntable, the plurality of damping members reducing either vibration and/or impact,
wherein the plurality of damping members are disposed on the circumference centered on the axis of rotation of the spindle motor, on the outer circumferential side of the position at which the yoke mounting portion is fixed to the sample holding member.

10. The sample surface inspection apparatus according to claim 8, further comprising:
a plurality of damping members each of which has one end connected to the sample holding member and the other end connected to the turntable, the plurality of damping members reducing either vibration and/or impact,
wherein the plurality of damping members are disposed on the circumference centered on the axis of rotation of the spindle motor, on the outer circumferential side of the position at which the yoke mounting portion is fixed to the Sample holding member.

11. The sample surface inspection apparatus according to claim 9,
wherein the plurality of damping members are disposed at equal intervals in the direction of the circumference centered on the axis of rotation of the spindle motor.

12. The sample surface inspection apparatus according to claim 10,
wherein the plurality of damping members are disposed at equal intervals in the direction of the circumference centered on the axis of rotation of the spindle motor.

13. The sample surface inspection apparatus according to claim 11,
wherein the supporting members and the damping members are disposed alternately along the direction of 41 the circumference centered on the axis of rotation of the spindle motor.

14. The sample surface inspection apparatus according to claim 12,
wherein the supporting members and the damping members are disposed alternately along the direction o f the circumference centered on the axis of rotation of 41 the spindle motor.

15. The sample surface inspection apparatus according to claim 13, further comprising:
a sample height position sensor that detects a height position of a surface of the sample,
wherein the focus driving mechanism adjusts a height position of the sample holding member and the height position of the sample held by the sample holding member, on the basis of the height position of the sample detected by the sample height position sensor.

16. The sample surface inspection apparatus according to claim 14, further comprising:
a sample height position sensor that detects a height position of a surface of the sample,
wherein the focus driving mechanism adjusts a height position of the sample holding member and the height position the sample held by the sample holding member, on the basis of the height position of the sample detected by the sample height position sensor.
